(19) United States
(12) Patent Application Publication
(10) Pub. No.: US 2013/0149866 A1
(43) Pub. Date: Jun. 13, 2013

(54) BAFFLE PLATE FOR SEMICONDUCTOR PROCESSING APPARATUS

(71) Applicant: JOHN CHRISTOPHER SHRINER, ALLEN, TX (US)

(72) Inventor: JOHN CHRISTOPHER SHRINER, ALLEN, TX (US)

(73) Assignee: TEXAS INSTRUMENTS INCORPORATED, Dallas, TX (US)

(21) Appl. No.: 13/316,967

(22) Filed: Dec. 12, 2011

(51) Int. Cl. H01L 21/311; H01L 21/02

(52) U.S. Cl. 438/694; 156/345.34; 156/345.29; 257/E21.259

(57) ABSTRACT

A baffle plate for redirecting a reactive gas flow within a process chamber of a semiconductor plasma processing apparatus includes a topside surface having a plurality of topside apertures for receiving the reactive gas flow and a bottomside surface having a plurality of bottomside apertures for emitting the reactive gas flow toward a semiconductor substrate. An outer portion of the baffle plate includes both topside apertures and bottomside apertures, while within an inner portion of the baffle plate for at least one of the topside surface and bottomside surface is a solid region throughout exclusive of any apertures. The inner portion has an outer dimension that is at least ten (10) percent of an outer dimension of the outer portion.

### FIELD

Disclosed embodiments relate to semiconductor integrated circuit (IC) device fabrication, more specifically to semiconductor plasma processing.

### BACKGROUND

Conventional semiconductor fabrication includes processing a substrate (e.g., a wafer), where the processing includes thermal oxidations, ion implantations, thin film depositions such as chemical vapor deposition (CVD) or plasma-enhanced CVD (PECVD) of metal, dielectric and semiconductor materials, etching processes with photolithographically-based masking patterns that define features such as a photoresist mask, and photoresist stripping processes. After an etch process has been completed, the photoresist is removed by a resist stripping technique, such as using organic strippers, oxidizing-type strippers, or dry stripping by plasma etching.

Conventional resist stripping apparatus comprise a resist stripping chamber, a microwave source for generating a reactive gas flow including plasma from at least one gas, and an applicator tube for introducing the reactive gas flow into the resist stripping chamber. Plasma is known to be a state of matter similar to gas in which a substantial portion of the components are ionized.

FIG. 1 is a cross sectional depiction of a conventional plasma processing apparatus 100 including a process chamber 140 comprising a known baffle plate 110, such as for photoresist stripping operations, descumming, etching, passivation, or removing organics. Apparatus 100 includes an applicator tube 115 that has an inlet 115a for receiving at least one process gas. Coils 120 are coupled to be driven by a Microwave power source 125. When biased by Microwave power source 125 the coils 120 emit microwaves that reach and excite the process gas or process gas mixture in applicator tube 115 to generate a plasma.

A liner 170 includes a central opening 138 spaced apart from the baffle plate 110 shown to form a plenum 174. The distal end of the applicator tube 115 is coupled to the opening 138 which directs the flow of the reactive gas flow to the baffle plate 110. Baffle plate 110 has an area large enough to be supported by the sidewalls 140a of the process chamber 140. Inside the process chamber 140 is a semiconductor substrate referred to herein as a wafer 122, supported on a substrate support 130 that is on a pedestal 127.

The substrate support 130 can include a heater, such as a resistive heating element to maintain the wafer 122 at a suitable temperature during processing. The wafer 122 can be introduced into and removed from the process chamber 140 through a substrate entry port (not shown) provided in the sidewall 140a. For example, the wafer 122 can be transferred under vacuum into the interior of the process chamber 140 from an etching chamber located proximate to process chamber 140.

Process chamber 140 also includes a bottom wall 140b and a cover 140c. The function of the baffle plate 110 is to change the path of the flow of the reactive gas flow to enable the reactive gas flow to be spread out evenly over the full area of the wafer 122, including the outer edge of the wafer 122 to provide uniform processing across the area of the wafer. Baffle plate 110 includes a topside surface 112 and a bottomside surface 111.

Baffle plate 110 comprises inner portion 110a, an outer portion 110b, and an outer ring 110e, which comprises inner portion 110a and outer portion 110b seen to provide an aperture pattern that reaches from a topside surface 112 of the baffle plate 110 to a bottomside surface 111 of the baffle plate 110. In one particular case the overall height of the baffle plate is 40 mm, while the bottom surface 111 where the reactive gases flow out from including towards the wafer 122 is 11 mm thick. Accordingly, although referred to herein and in the semiconductor industry as a “baffle plate” or simply a baffle, the baffle plate 110 and other baffle plates referred to herein can be considered to be manifolds as they have a spacing (a gap) between their top surface and their bottom surface.

The aperture pattern includes both inner apertures 110d that are angular within inner portion 110a that directs a portion of the reactive gas flow to die positions at or near the center of the wafer 122 outward to nearly the periphery of the wafer 122, and outer apertures 110c within outer portion 110b. The outer apertures 110c direct a portion of the reactive gas flow to positions at or near to the periphery of the wafer 122 to positions beyond the edge of the wafer 122.

Inner apertures 110d can be seen to include at least a portion that is within a projected area 139 defined by projecting vertically downward the area of the opening 138 onto the topside surface 112 of the baffle plate 110. The arrows shown in FIG. 1 depict the flow path of the reactive gas flow out from the opening 138 that can be seen to directly reach the inner apertures 110d within inner portion 110a, and through scatter from the solid regions of inner portion 110a reach the outer apertures 110c on the outer portion 110b of the baffle plate 110. The flow of the reactive gas flow through the inner apertures 110d can be seen to thus provide a direct flow path onto the wafer 122, albeit not a direct line of sight flow by providing an approximately 45 degree turn, which may be contrasted with the redirected (scattered and thus indirect) flow path involved including the two 90 degree turns shown when the reactive gas flow flows out from the outer apertures 110c.

Some applicator tube materials, such as aluminum oxide, are known to form outer layers during use that can flake off to release particles into the reactive gas flow that become entrained particles in the reactive gas flow as the reactive gas flow flows by in the applicator tube 115. The rate of particle addition can increase as the outer layer thickness increases. To reduce the concentration of entrained particles and as a result the concentration of particles added to the wafer 122 during processing in process chamber 140, maintenance is generally performed on the applicator tube 115 and the baffle plate 110 including a wet clean process to remove the outer layer on the applicator tube 115 and particles from the baffle plate 110. Such cleaning can reduce the concentration of particles introduced onto the wafer 122 during processing. However, the wet clean process results in downtime for the apparatus 100, and thus can be the cause of a significant loss of productivity for the apparatus 100.

### SUMMARY

Disclosed embodiments recognize that the particles that flake off the applicator tube in conventional plasma processing apparatus such as apparatus 100 that become entrained in the reactive gas flow which reach the inner apertures 110d of the baffle plate 110 provide a direct flow path to positions near the center of the semiconductor substrate referred to herein as a wafer which adds particles that can be energetic enough to damage features (e.g., lines) defined on the wafer. The velocity of the particles flowing through these “direct flow” inner apertures has been discovered to provide a momentum high enough to cause a ballistic-like impact on etched lines, such as metal lines or gate polysilicon lines, deforming or severing the lines, resulting in yield impacting defectivity of the affected die. Significantly, disclosed embodiments recognize that eliminating inner apertures of the baffle plate results in redirection of the entire reactive gas flow including its entrained particles that significantly slows of the speed of all particles, reducing the ballistic-like impact to the point where the particles no longer damage, or at least significantly reduce the damage to, lines or other defined features on the surface of the wafer.

Disclosed embodiments include baffle plates that exclude inner apertures in the inner portion of the baffle plate, which functions to redirect the reactive gas flow and its entrained particles away from the center of the wafer and die locations extending outward from the center to near the periphery of the wafer, resulting in pumping out most of the particles from the process chamber instead of the particles becoming incident on the wafer's top surface. Disclosed baffle plates include a solid inner region exclusive of apertures, such as excluding the inner apertures 110a described above on known baffle plate 110. Elimination of inner apertures has also been confirmed to largely solve the problem of elevated defect density on the wafer comprising line deformation including line severing.

Despite being exclusive of inner apertures and the resulting remote injection aspect of the reactive gas flow relative to the center of the wafer and die locations extending outward from the center to near the periphery of the wafer, disclosed baffle plates have also been confirmed to unexpectedly provide good process uniformity across the full area of the wafer. As described below, the across the wafer process uniformity for processes such as ashing of photoresist obtained using a disclosed baffle plate was found to be comparable (e.g., statistically indistinguishable) to that provided by conventional baffle plates, such as baffle plate 110 disclosed above. Accordingly, disclosed baffle plates largely solve the problem of elevated defect density on the wafer comprising line deformation including line severing while providing comparable process performance to conventional baffle plates, such as baffle plate 110 disclosed above.

### BRIEF DESCRIPTION OF THE DRAWINGS

FIG. 1 is a cross sectional depiction of a conventional plasma processing apparatus including a process chamber comprising a known baffle plate that includes inner apertures within the inner portion of the baffle plate.

FIG. 2 is a cross sectional depiction of an example plasma processing apparatus including a disclosed baffle plate where within the inner portion for at least one of topside surface and bottomside surface provides a solid inner region that is exclusive of topside apertures or bottomside apertures, according to an example embodiment.

FIGS. 3A and 3B are center amplified topside views and bottomside views, respectively, of a conventional baffle plate having inner apertures.

FIGS. 3C and 3D are center amplified topside views and bottomside views, respectively, of a disclosed baffle plate where within the inner portion for at least one of topside surface and bottomside surface a solid inner region is provided that is exclusive of topside apertures or bottomside apertures, according to an example embodiment.

### DETAILED DESCRIPTION

Example embodiments are described with reference to the drawings, wherein like reference numerals are used to designate similar or equivalent elements. Illustrated ordering of acts or events should not be considered as limiting, as some acts or events may occur in different order and/or concurrently with other acts or events. Furthermore, some illustrated acts or events may not be required to implement a methodology in accordance with this disclosure.

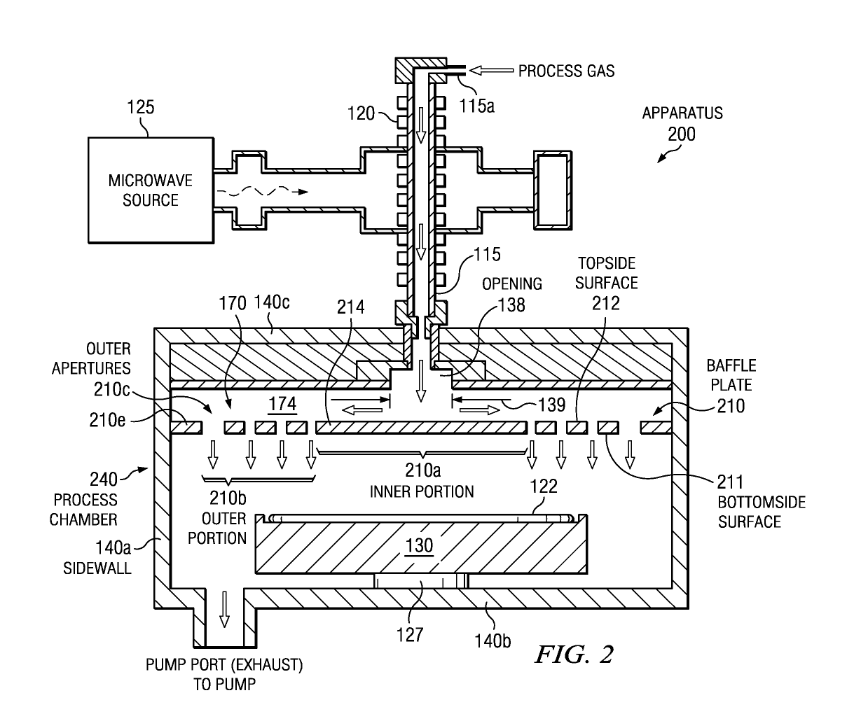

FIG. 2 is a cross sectional depiction of an example plasma processing apparatus 200 including a disclosed baffle plate 210 where within the inner portion 210a for at least one of topside surface 212 and bottomside surface 211 provides a solid inner region 214 that is exclusive of topside apertures or bottomside apertures, according to an example embodiment. The outer portion 210b of the baffle plate 210 includes outer apertures 210c that comprises both topside apertures and bottomside apertures generally aligned with one another. Apparatus 200 can be used for plasma processes including photoresist stripping operations, descumming, etching, surface passivation, or removing organics.

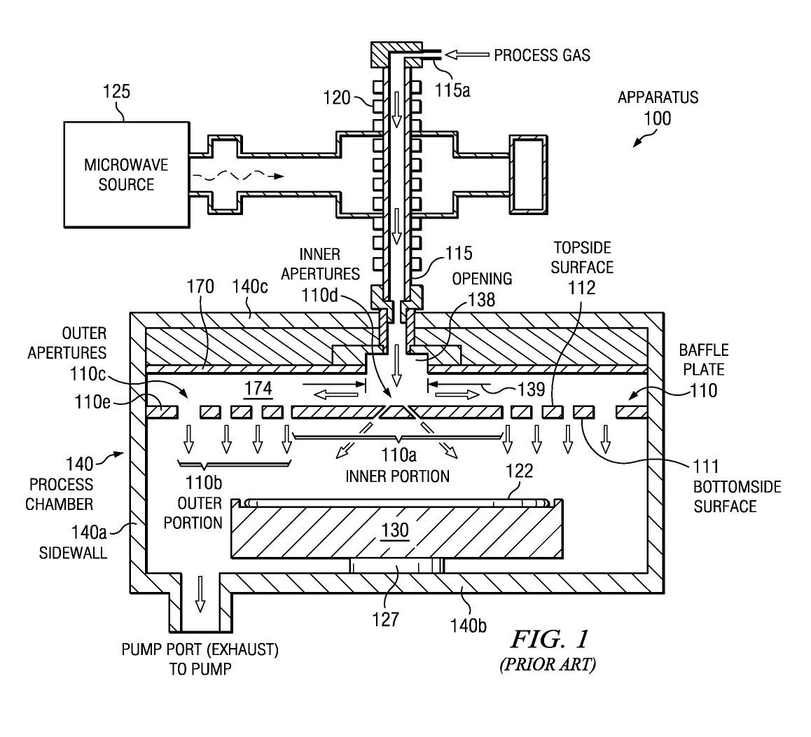

The area of the solid inner region 214 can be seen to be ≧ to the projected area 139 defined by projecting downward the area of the opening 138 in the liner 170 onto the topside surface 212 of the baffle plate 210. This feature of baffle plate 210 may be contrasted with known baffle plate 110 shown in FIG. 1 which includes a plurality of angular apertures 110b within the projected area 139. The outer dimension of solid inner portion 214 is generally at least ten (10) percent of an outer dimension of the outer portion 210b, and in another embodiment is at least twenty (20) percent of an outer dimension of the outer portion 210b.

Apparatus 200 includes a process chamber 240 having baffle plate 210 therein. In one embodiment the baffle plate 210 comprises aluminum. Apparatus 200 includes an applicator tube 115 that has an inlet 115a for receiving at least one process gas. Coils 120 are coupled to a Microwave power source 125. In one embodiment the applicator tube 115 comprises aluminum oxide. In another embodiment the applicator tube 115 comprises quartz.

When biased by microwaves from microwave power source 125 the coils 120 emit microwaves that reach and excites the process gas or process gas mixture in applicator tube 115 and generates a plasma state therefrom. The Microwave power source 125 can operate at an example frequency of about 2.45 GHz, and can be at a power in the range of about 500 to about 1500 W. The process gas is energized into the plasma state by the microwaves produced by Microwave power source 125.

The opening 138 of the liner 170 is spaced apart from the baffle plate 210 shown to form a plenum 174. The distal end (outlet) of the applicator tube 115 is coupled to the opening 138 to direct the flow of the reactive gas flow to the baffle plate 210 which is supported by the sidewalls 140a of the process chamber. Inside the process chamber 140 is a wafer 122 that is supported on a substrate support 130. Baffle plate 210 can be seen to include an aperture pattern that is only within outer portion 210b that reaches from a topside surface 212 of the baffle plate 210 to a bottomside surface 211 of the baffle plate 110.

The arrows shown in FIG. 2 depict the flow path of the reactive gas flow from the opening 138 which can be seen to all scatter off the solid inner portion 210a to reach the outer apertures 210c on the outer portion 210b of the baffle plate 210, and then out from the outer apertures 210c including onto the periphery of the wafer 122. Due to the area of the solid inner region 214 being ≧ to the projected area 139 of the baffle plate 210, unlike the reactive gas flow provided by known baffle plate 110 shown in FIG. 1, there is no reactive gas flow relative to the center of the wafer 122 and die locations extending outward from the center to near the periphery of the wafer 122. Despite being exclusive of conventional inner apertures and the resulting remote injection aspect of the reactive gas flow to the center of the wafer 122 and die locations extending outward from the center to near the periphery of the wafer 122, disclosed baffle plates have been confirmed to unexpectedly provide good process uniformity across the full area of the wafer. As described below, the across the wafer process uniformity for processes such as ashing of photoresist obtained using a disclosed baffle plate such as baffle plate 210 was found to be comparable (e.g., statistically indistinguishable) to that provided by conventional baffle plates, such as known baffle plate 110 disclosed above.

Disclosed baffle plates thus provide redirection of the reactive gas flow that functions to slow the speed of the particles travelling in the reactive plasma, and eliminates (or at least substantially reduces) particles from reaching the surface of the wafer 122, and eliminates or substantially reduces particles from ballistically damaging lines on the wafer 122. As described below, disclosed baffle plates have comparable good process uniformity when compared with conventional baffle plates, with the added benefit of directing particles out to the edge of the process chamber where they are pumped out of the process chamber, instead of directing them to the wafer surface at high speed, where they can damage lines on the wafer, such as gate poly lines or metal (e.g., aluminum) lines.

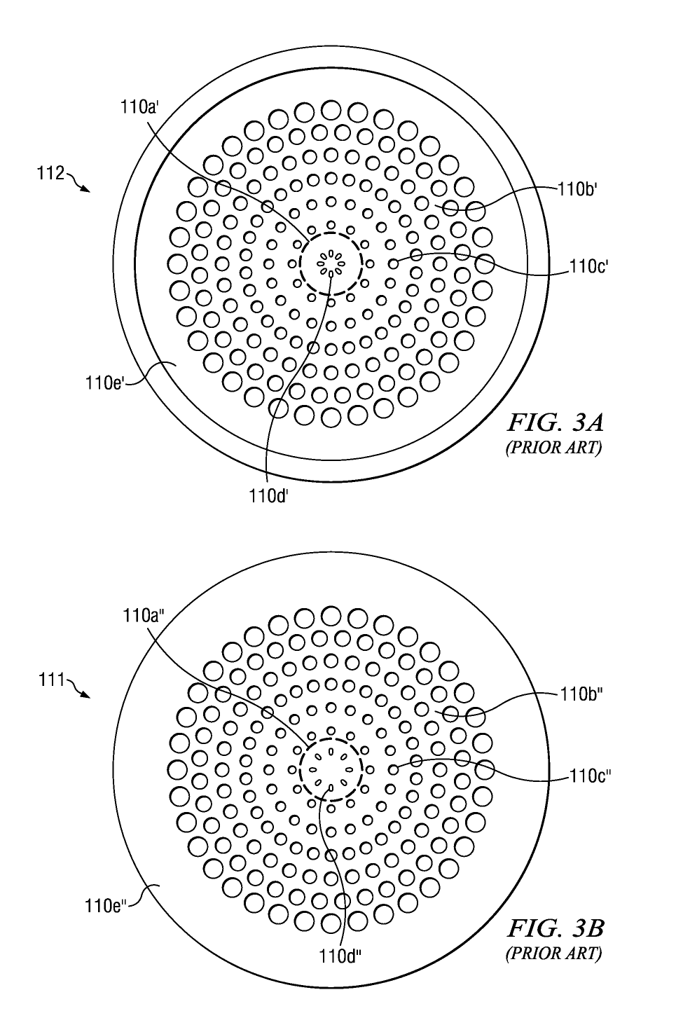

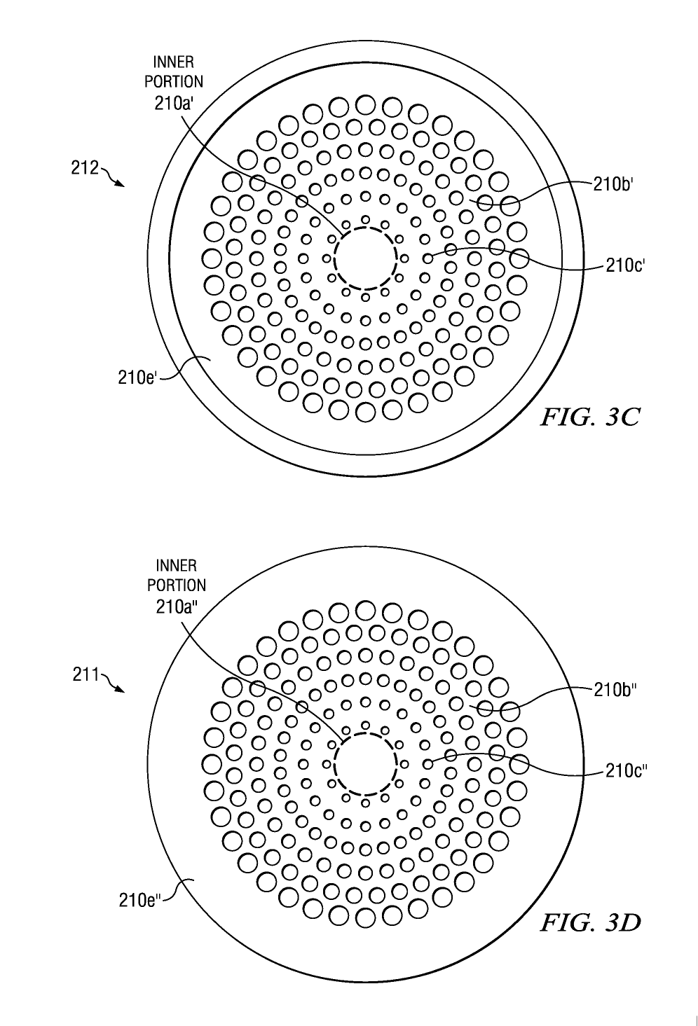

FIGS. 3A and 3B are center amplified topside surface 112 and bottomside surface 111 views, respectively, for a conventional baffle plate 110 having inner apertures shown as 110d′ on the topside surface 112 and inner apertures 110d″ on bottomside surface 111. The inner portion 110a of the baffle plate 110 is shown as 110a′ on the topside surface 112 and 110a″ on the bottomside surface 111. The outer portion 110b of the baffle plate 110 is shown as 110b′ on the topside surface 112 and 110b″ on the bottomside surface 111. The outer apertures of the baffle plate 110 is shown as 110c′ on the topside surface 112 and 110c″ on the bottomside surface 111. The outer ring 110e of the baffle plate 110 is shown as 110e′ on the topside surface 112 and 110e″ on the bottomside surface 111. The outer ring 110e is solid.

The topside surface and bottomside surface views in FIGS. 3A and 3B reveal inner apertures 110d′ and 110d″ in the topside surface 112 and bottomside surface 111 are in the shape of daisy petals, along with concentric rows of circular outer apertures 110c′ and 110c″. As described above, disclosed embodiments recognize particles traveling at high velocity entrained in the reactive gas flow that pass through the inner apertures 110d comprising inner apertures 110d′ and 110d″ from the topside surface to the bottomside surface and out from the bottomside surface can have sufficient momentum to damage, and in some cases sever, lines on the top surface of the wafer being processed.

FIGS. 3C and 3D are center amplified views of a topside surface 212 and a bottomside surface 211 respectively, of a disclosed baffle plate 210 where the topside surface 212 and bottomside surface 211 reveal within the inner portion 210a for both the topside surface 212 and the bottomside surface 211 consist of solid regions exclusive of any apertures, according to an example embodiment. The outer apertures 210c′ of the topside surface 212 are for receiving a reactive gas flow, such as from opening 138 coupled to the distal end of applicator tube 115 as described above after scatter from inner portion 210a, while the outer apertures 210c″ on the bottomside surface 211 are for emitting the reactive gas received from outer apertures 210c′ of the topside surface 212 for flowing towards the wafer. The plurality of topside outer apertures 210c′ and plurality of bottomside outer apertures 210c″ shown have round cross sections and are both arranged in concentric rows. The cross sections in the concentric rows can be seen to increase in diameter as a radius increases outward from a center of the baffle plate.

As shown in FIGS. 3C and 3D, the baffle plate 210 is generally circular. The topside surface 212 and bottomside surface 211 are generally joined together to provide one-piece body.

The inner portion 210a of the baffle plate 210 is shown as 210a′ on the topside surface 212 and 210a″ on the bottomside surface 211. The outer portion 210b of the baffle plate 210 is shown as 210b′ on the topside surface 212 and 210b″ on the bottomside surface 211. The outer ring 210e of the baffle plate 210 is shown as 210e′ on the topside surface 212 and 210e″ on the bottomside surface 211.

The apertures on baffle plate 210 are thus all outer apertures 210c within the annular shaped (ring-shaped) outer portion 210b of the baffle plate. The inner portion 210a of the baffle plate 210 comprising inner portion 210a′ on the topside surface 212 and inner portion 210a″ on the bottomside surface 211 can be seen to have an outer dimension (diameter or radius) that is at least ten (10) percent of an outer dimension (diameter or radius) the outer portion 210b shown as 210b′ on the topside surface 212 and 210b″ on the bottomside surface 211. The topside surface and the bottomside surfaces within inner portion 210 shown as 210a′ and 210a″ each consist of solid regions exclusive of any apertures, which results in redirecting the reactive gas flow and its entrained particles resulting in the particle velocity slowing down due to the changes in direction resulting in a reduction of damage to lines on the wafer being plasma processed.

In one particular example the inner portion 210a on the topside surface 212 and bottomside surface 211 has a diameter of 68 mm, the outer edge diameter of the outer portion 210b on the topside surface 212 and bottomside surface 211 is 283 mm, while the overall chamber-side diameter defined by the edge of outer ring 210e of the baffle plate is 367 mm. In this particular example, the inner portion has an outer dimension that about twenty four (24) percent of an outer dimension of the outer portion.

Disclosed embodiments include methods of processing a semiconductor substrate (e.g., wafer) using processing chamber having a disclosed baffle plate. The method comprises flowing a reactive gas flow through a distal end of an applicator tube coupled to an opening in a process chamber aligned to direct the reactive gas flow to a baffle plate within the process chamber. A plasma process is performed on a patterned layer, or to form a patterned layer, on a semiconductor substrate involving a chemical reaction that includes at least one component of the reactive gas flow.

Disclosed apparatus can be used for a variety of processes including for stripping photoresist, descumming, etching, surface passivation and removing organics. In a photoresist stripping process, the plasma process removes (or strips) photoresist from the wafer surface. For surface passivation, the wafer no longer has photoresist thereon and the process chamber is instead used to passivate the surface of the wafer, such as to residual halogen materials such as Cl₂ and HBr gases used in the process chamber of an immediately previous process, such as to etch polysilicon, which can cause corrosion.

For example, in an example polysilicon gate etch process, a photoresist strip step is in the middle of the gate etch process which removes the resist (in an etch chamber), then the rest of the gate is etched in the etch chamber, such as using Cl₂/HBr/O₂ plasma chemistries. The wafer can then enter a disclosed apparatus for passivation processing comprising a non-CF₄ gas, typically comprising O₂, while no photoresist is on the wafer to remove residues from Cl₂ and HBr gases used in the preceding etch process from the wafer surface to passivate the surface of the wafer. Non-CF₄ passivation chemistry can also eliminate defects from corrosion of the pedestal 127 and eliminate the high cost of pedestal replacements.

The primary passivation process reaction in this particular case is Cl₂+HBr+O₂->HCl (gas)+H₂O (gas)+Br₂ (gas), so the chlorine reacts to form HCl, which is then is pumped out of the process chamber before the substrate exits the apparatus. Passivation can thus eliminate an HCl formation reaction when the wafer is exposed to moisture under atmosphere.

Although disclosed processing apparatus described above are described for single wafer processing, if multiple applicator tubes 115 are added to one large chamber multiple substrates (e.g., wafers) may be simultaneously processed. Apparatus 200 can thus be replicated in an array.

Moreover, generally any process run in a process chamber where a deposition forms above the baffle plate can benefit from disclosed baffle plates. Particles on the wafer surface are reduced or eliminated, and feature (e.g., line) damage or destruction can be reduced or eliminated with disclosed baffle plates. Disclosed baffle plates provide another significant advantage. Wet cleans on the process chamber to the baffle plate and applicator tube can be completed at “scheduled intervals”, as opposed to in reaction to the detection of “post defect failures”.

As noted above, disclosed baffle plates provide an unexpected result. Despite being exclusive of inner apertures so that remote injection is relied on entirely for supply of reactive gas flow to the center of the wafer 122 and die locations extending outward from the center to near the periphery of the wafer 122, disclosed baffle plates have been confirmed to unexpectedly provide good process uniformity across the full area of the wafer. In the photoresist example described below, disclosed baffle plates provide process uniformity for photoresist removal across the full area of the wafer comparable to the process uniformity obtained using conventional baffle plates, such as known baffle plate 110 disclosed above.

The performance for ashing photoresist in a plasma processing apparatus having a disclosed baffle plate 210 was compared against a control plasma processing apparatus having known baffle plate 110. Chamber ash rate tests were performed and it was found that the disclosed baffle plate 210 and known baffle plate 110 both had similar (acceptable) ash rates and across the wafer ash rate non-uniformity measurements. Although particle counts are not described in this Example, particle counts for plasma processes using the disclosed baffle plate 210 have been found to be consistently and significantly lower as compared to particle counts when using for known baffle plate 110.

Regarding the ash rate tests, a blanket photoresist wafer having about 2.5 μm of photoresist was pre-measured in order to determine the thickness of the photoresist at various locations on the wafer surface. The wafer was run through the process chamber using a photoresist ashing process recipe that is similar a production ashing process used. The wafer was then post measured for photoresist thickness in the same locations as the pre-measurement recipe.

The post measurement thickness was subtracted from the pre-measurement thickness and then divided by the time that the wafer ran in the ash chamber process. This calculation determined the photoresist ash rate provided by the ash chamber. The delta photoresist removed for each individual point was also used to calculate the “maximum delta minus the minimum delta”, which was then plotted in order to determine the ash chamber across wafer non-uniformity. This same procedure was used to compare the ash rate and ash rate non-uniformity across the disclosed baffle plate 210 and known baffle plate 110, on both baked photoresist and non-baked photoresist. All comparisons made were found to be well within the normal acceptable range for the ashing rate and as well as ashing rate across the wafer non-uniformity measurements, with generally all results obtained being statistically indistinguishable between disclosed baffle plate 210 and known baffle plate 110.

Those skilled in the art to which this disclosure relates will appreciate that many other embodiments and variations of embodiments are possible within the scope of the claimed invention, and further additions, deletions, substitutions and modifications may be made to the described embodiments without departing from the scope of this disclosure.

We claim:

1. A baffle plate for redirecting a reactive gas flow within a process chamber of a semiconductor plasma processing apparatus, comprising:
a topside surface having a plurality of topside apertures for receiving said reactive gas flow, and
a bottomside surface having a plurality of bottomside apertures for emitting said reactive gas flow toward a semiconductor substrate;
wherein an outer portion of said baffle plate includes both said plurality of topside apertures and said plurality of bottomside apertures, and
wherein within an inner portion of said baffle plate for at least one of said topside surface and said bottomside surface provides a solid region throughout exclusive of any said plurality of topside apertures or said plurality of bottomside apertures, and
wherein said inner portion has an outer dimension that is at least ten (10) percent of an outer dimension of said outer portion.

2. The baffle plate of claim 1, wherein said inner portion provides said solid region on both said topside surface and said bottomside surface.

3. The baffle plate of claim 2, wherein said plurality of topside apertures and said plurality of bottomside apertures have round cross sections and are both arranged in concentric rows.

4. The baffle plate of claim 3, wherein said cross sections in said concentric rows increase in diameter as a radius increases outward from a center of said baffle plate.

5. The baffle plate of claim 1, wherein said baffle plate comprises aluminum.

6. The baffle plate of claim 1, wherein said inner portion has an outer dimension that is at least twenty (20) percent of an outer dimension of said outer portion.

7. A plasma processing apparatus, comprising:
a process chamber having sidewalls, a bottom wall and a cover;
an applicator tube having an inlet for receiving at least one process gas;
a RF source coupled to coils operable to emit radiation that generate a reactive gas flow from said process gas, wherein said reactive gas flow is introduced though an opening into said process chamber coupled to a distal end of said applicator tube, and
a baffle plate in said process chamber, wherein said baffle plate comprises:
a topside surface having a plurality of topside apertures for receiving said reactive gas flow, and
a bottomside surface having a plurality of bottomside apertures for emitting said reactive gas flow toward a semiconductor substrate on said process chamber;
wherein an outer portion of said baffle plate includes both said plurality of topside apertures and said plurality of bottomside apertures,
wherein within an inner portion of said baffle plate for at least one of said topside and said bottomside provides a solid region throughout that is exclusive of any said plurality of topside apertures or said plurality of bottomside apertures, and
wherein said inner portion has an outer dimension that provides an area at least equal to an area of said opening.

8. The apparatus of claim 7, wherein said applicator tube comprises aluminum oxide.

9. The apparatus of claim 7, wherein said applicator tube comprises quartz.

10. The apparatus of claim 7, wherein said inner portion provides said solid inner region on both said topside surface and said bottomside surface.

11. The apparatus of claim 10, wherein said plurality of topside apertures and said plurality of bottomside apertures both have round cross sections and are both arranged in concentric rows.

12. The apparatus of claim 11, wherein said cross sections in said concentric rows increase in diameter as a radius increases outward from a center of said baffle plate.

13. The apparatus of claim 7, wherein said baffle plate comprises aluminum.

14. A method of processing a semiconductor substrate, comprising:
flowing a reactive gas flow through distal end of an applicator tube coupled to an opening in a process chamber aligned to direct said reactive gas flow to a baffle plate within said process chamber,
wherein said baffle plate comprises:
a topside having a plurality of topside apertures for receiving said reactive gas flow, and
a bottomside surface having a plurality of bottomside apertures for emitting said reactive gas flow toward said semiconductor substrate;
wherein an outer portion of said baffle plate includes both said plurality of topside apertures and said plurality of bottomside apertures, and
wherein an inner portion of said baffle plate for at least one of said topside and said bottomside provides a solid region throughout that is exclusive of any said plurality of topside apertures or said plurality of bottomside apertures, wherein said baffle plate distributes said reactive gas flow across a surface of said semiconductor substrate,
wherein said inner portion has an outer dimension that provides an area at least equal to an area of said opening, and
performing a plasma process on a patterned layer on said semiconductor substrate comprising a chemical reaction including at least one component of said reactive gas flow.

15. The method of claim 14, wherein said plasma process comprises a non-CF₄ O₂ comprising passivation process that follows an etch and a photoresist strip process.

16. The method of claim 14, wherein said patterned layer comprises polysilicon.

17. The method of claim 14, wherein said plasma process comprises stripping photoresist following an aluminum etch process.

18. The method of claim 14, wherein said applicator tube comprises aluminum oxide.
